(19) United States
(12) Patent Application Publication
(10) Pub. No.: US 2026/0269479 A1
(43) Pub. Date: Sep. 10, 2026

(54) ANTENNA MODULE AND A METHOD FOR FORMING THE ANTENNA MODULE

(71) Applicant: Agency for Science, Technology and Research, Singapore (SG)

(72) Inventor: Teck Guan LIM, Singapore (SG)

(21) Appl. No.: 19/164,452

(22) PCT Filed: Mar. 1, 2024
(86) PCT No.: PCT/SG2024/050126

§ 371 Date: Sep. 11, 2025

(30) Foreign Application Priority Data
Mar. 13, 2023 (SG) 10202300685X

(51) Int. Cl. H01Q 9/04; G01R 29/08; H04B 17/10; H04B 17/12

(52) U.S. Cl. CPC H01Q 9/0457; G01R 29/0878; H04B 17/102; H04B 17/12

(57) ABSTRACT

An antenna module is described in an embodiment. The antenna module comprises: a substrate, a first sensor formed on the substrate, and an antenna element provided on the first sensor. The antenna element is adapted to emit electromagnetic waves in a direction away from the substrate to form a main radiation field and in a direction toward the substrate to form a back-radiation field. The first sensor is formed between the substrate and the antenna element and is adapted to measure the back-radiation field emitted by the antenna element. A method for forming the antenna module is also described.

### TECHNICAL FIELD

The present disclosure relates to an antenna module and a method for forming the antenna module.

### BACKGROUND

An antenna array provides high gain and beam steering capability. For beam steering, it is achieved by controlling the phase and the magnitude of the radio-frequency (RF) signal feed to each antenna element of the antenna array. The phase of the RF signal is dependent on the RF routing (transmission line) design between the monolithic microwave integrated circuit (MMIC) and the antenna, and the MMIC performance. Due to manufacturing tolerances, in practice, the routing and the MMIC have imperfections which can introduce phase and power errors to the RF signal feed. These affect the beam steering performance of the antenna array. Furthermore, the MMIC output can be affected by product lifecycles and reliability. One way of overcoming these problems is by determining the errors and making compensation in the MMIC in a process known as antenna array calibration. However, this requires a mechanism to provide feedback for the antenna array system to introduce the compensation.

On a modular level, each of the antenna elements may be in the form of an Antenna-in-Package (AiP). In an AiP, an antenna, RF circuit and an MMIC are integrated within the package. With an increasing level of sophistication of wireless applications, higher operating bandwidth, and higher functionality, integration of such a feedback mechanism with the AiP is desired.

Present solutions include (i) having a monitoring probe/sensor at the side or at the front of the antenna for coupling to the main radiation power of the antenna or (ii) incorporating additional RF circuits within the AiP to serve the desired integration purpose. However, these solutions are undesirable as they either interfere with the antenna performance and thereby require re-designing of the antenna to accommodate the monitoring probe/sensor, or increase costs and fabrication complexity of the AiP due to requirements in relation to increasing dielectric layer thicknesses and the number of metal layers for incorporating these additional RF circuits in the AiP. These problems are exacerbated as the operating frequency of the antenna element or antenna array increases which leads to smaller element spacings in the antenna array.

It is therefore desirable to provide an antenna module and a method for forming the antenna module which addresses the aforementioned problems and/or provide a useful alternative. Further, other desirable features and characteristics will become apparent from the subsequent detailed description and the appended claims, taken in conjunction with the accompanying drawings and this background of the disclosure.

### SUMMARY

Aspects of the present application relate to an antenna module and a method for forming the antenna module.

In accordance with a first aspect, there is provided an antenna module comprising: a substrate; a first sensor formed on the substrate; and an antenna element provided on the first sensor, the antenna element being adapted to emit electromagnetic waves in a direction away from the substrate to form a main radiation field and in a direction toward the substrate to form a back-radiation field, wherein the first sensor is formed between the substrate and the antenna element and is adapted to measure the back-radiation field emitted by the antenna element.

By having the first sensor formed on the substrate and between the substrate and the antenna element for measuring the back-radiation field emitted by the antenna element, the output of the antenna element can be monitored which can provide feedback to a performance of the antenna element for calibration. The first sensor is positioned at the back of the antenna element for measuring its back-radiation field by coupling to unwanted back-radiation power emitted by the antenna element instead of its main forward radiation field/beam. This minimizes disturbances or interferences on an operation of the antenna element, thereby enabling monitoring of an output of the antenna element without affecting its normal operation. Furthermore, integration and fabrication complexity related to incorporating additional measurement circuits within the antenna element is negated in the present antenna module as the first sensor is formed on the substrate. This allows the design and formation of the first sensor (which may include measurement circuits) directly on the substrate, thereby overcoming an integration design/routing complexity needed if these measurement circuits are instead formed in the antenna element. The antenna module of the present disclosure therefore provides in-situ antenna monitoring capability without increasing the complexity of an antenna design.

The antenna element may comprise: an antenna feed line provided on and spaced apart from the first sensor; a ground plane having an aperture, the ground plane being formed on the antenna feed line; and a patch antenna formed over the aperture and the antenna feed line, the patch antenna being adapted to emit the electromagnetic waves, wherein the antenna feed line may be electrically connected to a radio-frequency (RF) output of a monolithic microwave integrated circuit (MMIC) or a radio-frequency integrated circuit (RFIC) and may be capacitively coupled to the patch antenna through the aperture for controlling emission of the electromagnetic waves.

Where the first sensor may comprise a dipole antenna having a sensor longitudinal axis and the antenna feed line may be in the form of an elongated shape and having a longitudinal axis, the antenna feed line may be arranged to overlap with the dipole antenna and to have the longitudinal axis of the antenna feed line substantially parallel to the sensor longitudinal axis.

The aperture may be arranged to overlap with the dipole antenna and to have the elongated portion of the aperture substantially perpendicular to the sensor longitudinal axis.

The antenna module may comprise: a second sensor provided on the substrate, wherein the second sensor may be arranged substantially orthogonally to the first sensor and may be adapted to measure the back-radiation field from the antenna element.

In accordance with a second aspect, there is provided a method for an antenna module. The method comprising: (i) providing a substrate; (ii) forming a first sensor on the substrate; and (iii) providing an antenna element on the first sensor, the antenna element being adapted to emit electromagnetic waves in a direction away from the substrate to form a main radiation field and in a direction toward the substrate to form a back-radiation field, wherein the first sensor is formed between the substrate and the antenna element and is adapted to measure the back-radiation field emitted by the antenna element. Providing the antenna element on the first sensor may comprise: providing an antenna feed line on and spaced apart from the first sensor; forming a ground plane having an aperture on the antenna feed line; and forming a patch antenna over the aperture and the antenna feed line, the patch antenna being adapted to emit the electromagnetic waves, wherein the antenna feed line may be electrically connected to a radio-frequency (RF) output of a monolithic microwave integrated circuit (MMIC) or a radio-frequency integrated circuit (RFIC) and may be capacitively coupled to the patch antenna through the aperture for controlling emission of the electromagnetic waves.

Wherein the first sensor may comprise a dipole antenna having a sensor longitudinal axis and the antenna feed line may be in the form of an elongated shape and having a longitudinal axis, the method may comprise providing the antenna feed line to overlap with the dipole antenna and to have the longitudinal axis of the antenna feed line substantially parallel to the sensor longitudinal axis of the dipole antenna.

The aperture may be in the form of a H-shape having an elongated portion and two end portions formed at each end of the elongated portion, and each of the two end portions may be perpendicular to the elongated portion.

Forming the ground plane having the aperture on the antenna feed line may comprise arranging the aperture to overlap with the dipole antenna and to have the elongated portion of the aperture substantially perpendicular to the sensor longitudinal axis.

The antenna feed line, the ground plane and the patch antenna may be integrated to form an antenna-in-package (AIP) structure.

The first sensor may comprise an inductor.

The method may comprise providing a second sensor on the substrate, wherein the second sensor may be arranged substantially orthogonally to the first sensor and may be adapted to measure the back-radiation field from the antenna element.

The method may comprise: optimizing parameters associated with the antenna element to maximize a bandwidth of the patch antenna, the parameters include a shape of the aperture, dimensions of the patch antenna and a separation distance between the patch antenna and the ground plane; and optimizing a length of the dipole antenna based on the optimized parameters associated with the antenna element to maximize a coupled power between the dipole antenna and the antenna element. Therefore, for an embodiment having a dipole antenna as the first sensor, the first sensor can be used to optimize the performance of the antenna element. This provides an additional parameter to optimize an antenna performance (e.g. by increasing a bandwidth of the antenna).

Wherein the substrate may include a printed-circuit board (PCB) having a ground layer on a top surface of the PCB, forming the first sensor on the substrate may comprise removing a portion of the ground layer on the top surface of the PCB and forming the first sensor on a portion of the top surface of the PCB at which the portion of the ground layer is removed.

The first sensor may be adapted to receive a calibration signal and to transmit the calibration signal as calibration electromagnetic waves to the antenna element for calibrating the antenna element.

It should be appreciated that features relating to one aspect may be applicable to the other aspects. Embodiments provide an antenna module and a method for forming the antenna module. Particularly, by having the first sensor formed on the substrate and between the substrate and the antenna element for measuring a back-radiation field emitted by the antenna element, the output of the antenna element can be monitored which can provide feedback to a performance of the antenna element for calibration. The first sensor is positioned at the back of the antenna element for measuring its back-radiation field by coupling to unwanted back-radiation power emitted by the antenna element instead of its main forward beam/signal. This minimizes disturbances or interferences on an operation of the antenna element, enabling monitoring of an output of the antenna element without affecting its normal operation. Further, integration and fabrication complexity related to incorporating additional measurement circuits in the antenna element is negated in the present antenna module as the first sensor is formed on the substrate. This allows the design and formation of the first sensor (which may include measurement circuits) directly on the substrate, thereby overcoming an integration design/routing complexity needed if these measurement circuits are instead formed within the antenna element. The antenna module of the present disclosure therefore provides in-situ antenna monitoring capability without increasing a complexity of an antenna design. Moreover, in an embodiment where the first sensor includes a dipole antenna, the first sensor can be used to optimize an antenna performance. This provides an additional parameter to optimize the antenna performance (e.g. by increasing a bandwidth of the antenna).

### BRIEF DESCRIPTION OF THE DRAWINGS

Embodiments will now be described, by way of example only, with reference to the following drawings, in which:

FIGS. 1A and 1B are schematic diagrams of an antenna module in accordance with an embodiment, where FIG. 1A is a schematic diagram showing a perspective view of the antenna module and FIG. 1B is a schematic diagram showing a cross-sectional view of the antenna module;

FIG. 2 is a contour plot illustrating near radiation field of an antenna element of the antenna module of FIG. 1A in accordance with an embodiment;

FIG. 3 is a flowchart of a method for forming the antenna module of FIG. 1A in accordance with an embodiment;

FIG. 4 is a flowchart of a method for providing the antenna element on the sensor in relation to the method of FIG. 3 in accordance with an embodiment;

FIG. 5 is a flowchart of a method for forming the sensor on the substrate in relation to the method of FIG. 3 in accordance with an embodiment;

FIG. 6 is a schematic diagram of a top view of the antenna element of the antenna module of FIG. 1A in accordance with an embodiment;

FIG. 7 shows a variety of aperture shapes for use in the antenna module of FIG. 1A in accordance with an embodiment;

FIG. 8 is a simulated graph of decibel versus frequency to illustrate a response of an antenna without the presence of the sensor in accordance with an embodiment;

FIG. 9 is a simulated graph of decibel versus frequency to illustrate a response of the antenna in the presence of a sensor for varying sensor length in accordance with an embodiment; and

FIG. 10 is a simulated graph of decibel versus frequency to illustrate a coupled power of the sensor with the antenna for varying sensor length in accordance with an embodiment.

### DETAILED DESCRIPTION

Exemplary embodiments relate to an antenna module and a method for forming the antenna module.

In view of the problems raised in the background section, it is desired in an antenna technology that an RF signal output of the MMIC is measured or monitored for antenna calibration and/or antenna performance assurance. It is also desired that the performance of individual antenna element is monitored for fault isolation. The present disclosure provides an antenna module comprising a sensor formed/provided at a backside of an antenna element/antenna on a substrate/PCB to measure a back-radiation field of the antenna element/antenna for monitoring a performance of the antenna element/antenna.

As described in relation to the exemplary embodiments below, an Antenna-in-Package (AiP) is considered. It should, however, be appreciated that other aperture-coupled antenna designs or antenna where the backside can be accessed can be used.

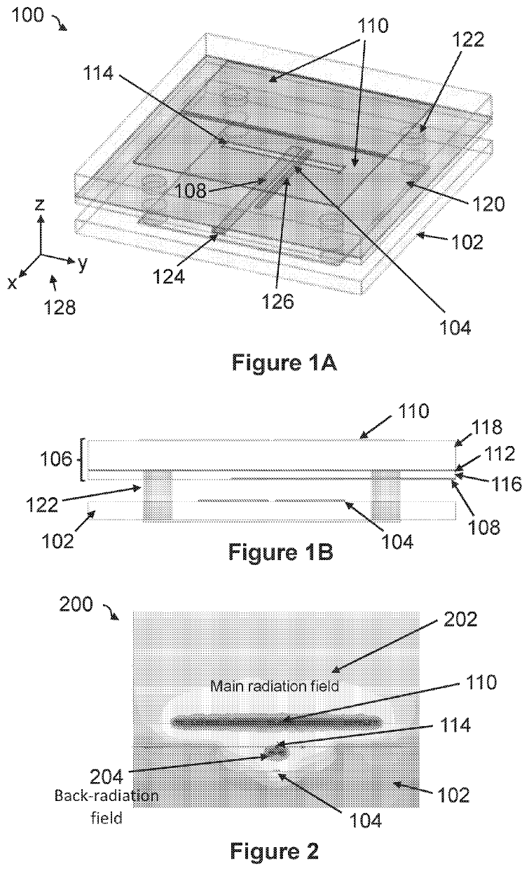

FIGS. 1A and 1B are schematic diagrams of an antenna module 100 in accordance with an embodiment. FIG. 1A is a schematic diagram showing a perspective view of the antenna module 100 and FIG. 1B is a schematic diagram showing a cross-sectional view of the antenna module 100.

The antenna module 100 includes a substrate 102, a sensor 104 formed on the substrate 102 and an antenna element 106 provided on or provided over the sensor 104. The sensor 104 is therefore formed between the antenna element 106 and the substrate 102. In the present embodiment as shown in relation to FIG. 1B, there is a spacing between the antenna element 106 and the sensor 104. The antenna element 106 is adapted to emit electromagnetic waves in a direction away from the substrate 102 to form a main radiation field and in a direction toward the substrate 102 to form a back-radiation field. The sensor 104 is adapted to measure the back-radiation field emitted by the antenna element 106. This is illustrated in relation to FIG. 2 below.

In the present embodiment, the antenna element 106 comprises an aperture coupled patch antenna (ACPA) structure. The ACPA structure is used in the present embodiments because it has one of the widest operating bandwidths, which is desired in modern current high data rate communication.

As shown in FIGS. 1A and 1B, the ACPA structure includes three electrically conductive layers (e.g. made of metal). A first electrically conductive layer includes an antenna feed line 108 to connect (feed) a RF output signal from a MMIC (not shown) to a patch antenna 110. The antenna feed line 108 is opened terminated and is used to capacitively coupled the RF output signal to the patch antenna 110 for controlling emission of electromagnetic waves from the patch antenna 110. A second electrically conductive layer includes a ground plane 112 having an aperture 114 or a slot, and is formed on or above the antenna feed line 108. The patch antenna 110 acts as a third electrically conductive layer and is formed over or above the aperture 114 and the antenna feed line 108. The patch antenna 110 is a planar antenna use for wireless communication and radar applications. The patch antenna 110 is capable of emitting electromagnetic waves and in the present embodiment, it is the back-radiation field of the patch antenna 110 which is measured using the sensor 104. In the present embodiment, the ground plane 112 is formed between the patch antenna 110 and the antenna feed line 108.

A design of the ACPA with the sensor is shown in FIG. 1B where a first dielectric layer 116 is formed between the ground plane 112 and the antenna feed line 108 and a second dielectric layer 118 is formed between the ground plane 112 and the patch antenna 110. In the present embodiment, the patch antenna 110 is formed on the second dielectric layer 118. In other embodiments, the patch antenna 110 can be formed within a dielectric layer. In the present embodiment, the substrate 102 includes a printed circuit board (PCB). Depending on a design or layout of the ACPA structure, the PCB is provided with a ground layer 120 on a top surface of the PCB (i.e. the surface facing the ACPA structure) and components of the PCB (not shown) can be electrically connected to the components of the ACPA structure using through mold via (TMV) 122 and solder bumps. In the present embodiment, the sensor 104 is formed or provided on a portion of the top surface of the PCB at which a portion of the ground layer is absent or has been removed.

The antenna feed line 108, the ground plane 112 and the patch antenna 110 of the ACPA structure can be integrated with a MMIC or a Radio-Frequency Integrated Circuit (RFIC) to form an antenna-in-package (AiP). As shown in FIGS. 1A and 1B, the AiP is assembled on the substrate 102 to form the antenna module 100. The sensor 104 is formed on the substrate 102 and between the substrate 102 and the AiP. The sensor 104 is configured to measure or detect back-radiation electromagnetic waves output by the patch antenna 110 of the AiP, instead of a main beam signal produced at a front of the patch antenna 110. By measuring the back-radiation output by the patch antenna 110, a RF output signal by the MMIC at the antenna feed input can therefore be measured/detected and this feedback can be used for antenna calibration.

In the present embodiment, the antenna module 100 having the sensor 104 formed on the substrate 102 circumvents design and fabrication complexities in relation to incorporating a measurement probe/sensor within an antenna element by having the sensor 104 designed and formed directly on the substrate 102 instead of incorporating it within the AiP.

In the present embodiment, the sensor 104 comprises a dipole antenna but it should be appreciated that other suitable sensor, for example a sensor comprising an inductor, can be used.

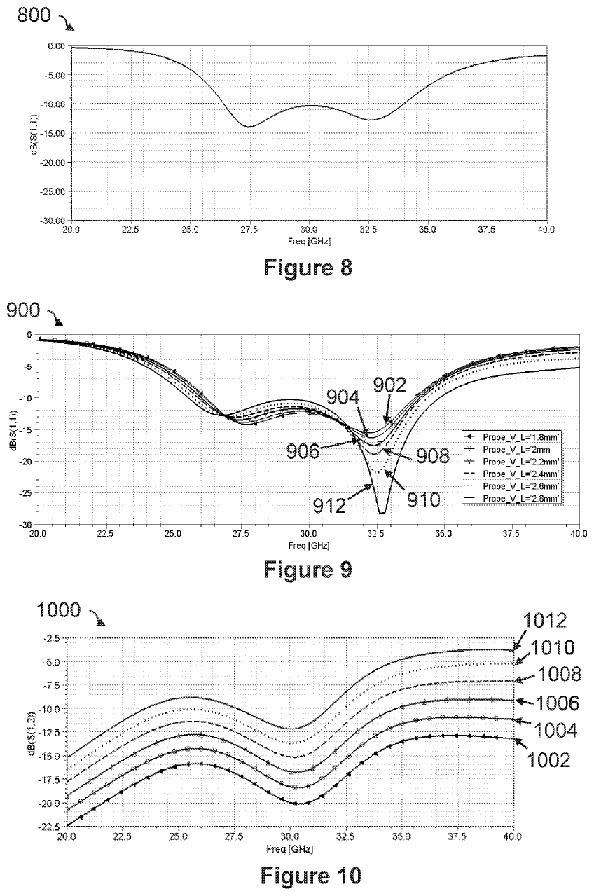

Simulation results in relation to the antenna module 100 are discussed below, in relation to FIGS. 8 to 10. For the simulations, a first simulation port (simulation port 1) 124 is connected to the antenna feed line 108 and a second simulation port (simulation port 2) 126 is connected to the sensor 104. Also shown in FIG. 1A are the Cartesian axes 128, namely, the x-, y- and z-axes to define an orientation of the antenna module 100. In the present embodiment, the ACPA structure or the antenna element 106 has a thickness of 0.52 mm and the antenna feed line 108 is placed at 0.30 mm above the substrate 102.

FIG. 2 is a contour plot 200 illustrating near radiation field emitted by the patch antenna 110 of the antenna module 100 of FIG. 1A in accordance with an embodiment.

As shown in FIG. 2, in relation to the ACPA structure of the present embodiment, the patch antenna 110 emits electromagnetic waves on a front side (i.e. facing away from the substrate 102) to form a main radiation field 202 and on a back side (i.e. facing towards the substrate 102) through the aperture/slot 114 to form a back-radiation field 204. The sensor 104 is formed on the substrate 102 at a back-side or behind the patch antenna 110, across the aperture/slot to couple the back-radiation field 204. Therefore, in the present antenna module 100, the back-radiation field 204 is used to measure the antenna RF signal output instead of the main radiation field 202 (or main beam signal) for antenna performance monitoring or calibration.

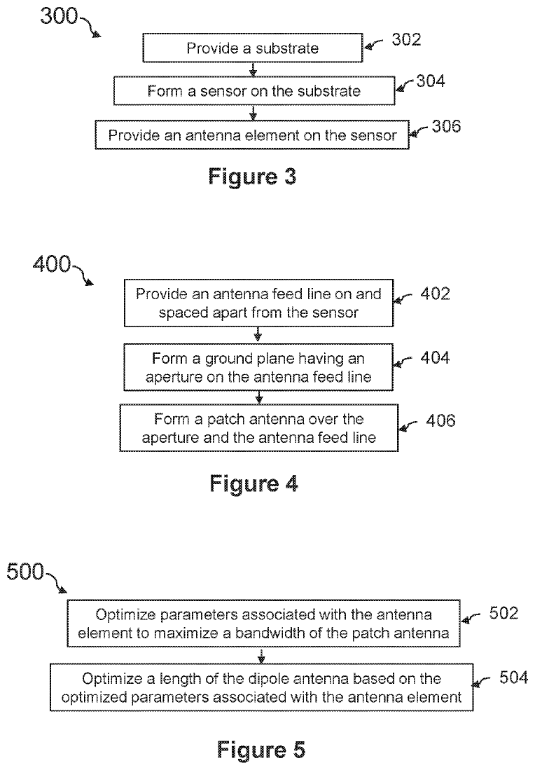

FIG. 3 is a flowchart of a method 300 for forming the antenna module of FIG. 1A in accordance with an embodiment.

In a step 302, the substrate 102 is provided. In the present embodiment, the substrate 102 includes a printed-circuit board (PCB) having a ground layer on a top surface of the PCB.

In a step 304, the sensor 104 is formed on the substrate 102. The sensor 104 is adapted to measure a back-radiation field emitted by the antenna element 106. In the present embodiment where the PCB having the ground layer 120 on its top surface is used, a portion of the ground layer 120 on the top surface of the PCB is removed prior to forming the sensor 104 on the portion of the top surface of the PCB.

In a step 306, the antenna element 106 is provided on the sensor 104. The antenna element 106 is adapted to emit electromagnetic waves in a direction away from the substrate to form the main radiation field 202 and in a direction toward the substrate to form the back-radiation field 204. In the present embodiment, the antenna element 106 includes an aperture coupled patch antenna (ACPA). Formation of the antenna element 106 or the ACPA is described in relation to FIG. 4 below.

FIG. 4 is a flowchart of a method 400 for providing the antenna element 106 on the sensor 104 in relation to the method 300 of FIG. 3 in accordance with an embodiment.

In a step 402, the antenna feed line 108 is provided on and spaced apart from the sensor 104. This is shown in relation to FIG. 1B above.

In a step 404, the ground plane 112 having the aperture 114 is formed on the antenna feed line 108.

In a step 406, the patch antenna 110 is formed over the aperture 114 and the antenna feed line 108.

The patch antenna 110 is adapted to emit electromagnetic waves on a front side to form the main radiation field 202 and on the back side through the aperture/slot 114 to form the back-radiation field 204, as shown in relation to FIG. 2. The antenna feed line 108 is electrically connected to a radio-frequency (RF) output of a MMIC (not shown) and is capacitively coupled to the patch antenna 110 for controlling emission of the electromagnetic waves. The aperture 114 is configured to control a bandwidth of the emitted electromagnetic waves from the patch antenna 110.

FIG. 5 is a flowchart of a method 500 for forming the sensor 104 on the substrate 102 in relation to the method 300 of FIG. 3 in accordance with an embodiment. Particularly, for forming the sensor 104, considerations can be taken to optimize one or more parameters of the sensor 104 in conjunction with a design of the antenna element 106 to optimize both the performances of the antenna element 106 and the sensor 104. In the present embodiment, the senor 104 comprises a dipole antenna and a length of the dipole antenna can be optimized to improve its performance.

In a step 502, parameters associated with the antenna element 106 are optimized to maximize a bandwidth of the patch antenna 110. The parameters include a shape of the aperture 114, dimensions of the patch antenna 110 and a separation distance between the patch antenna 110 and the ground plane 112.

In a step 504, a length of the dipole antenna 104 is optimized based on the optimized parameters associated with the antenna element 106 to maximize a coupled power between the dipole antenna 104 and the antenna element 106. As will be shown in relation to FIGS. 8 to 10 below, increasing a length of the dipole antenna 104 increases a bandwidth of the patch antenna 110 as well as a coupling power between the dipole antenna and the patch antenna 110.

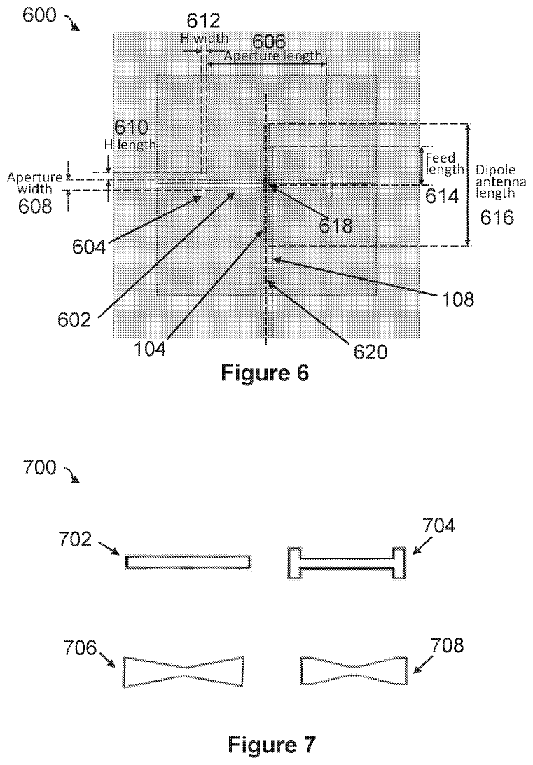

FIG. 6 is a schematic diagram of a top view 600 of the antenna element 106 of the antenna module 100 of FIG. 1A in accordance with an embodiment. In the present embodiment, the aperture 114 is in the form of a H-shape having an elongated portion 602 and two end portions 604 formed at each end of the elongated portion 602. As shown in FIG. 6, each of the two end portions 604 are perpendicular to the elongated portion 602.

To optimize antenna and coupling performances of the antenna module 100 in the present embodiment, co-designing of the antenna element 106 (in the present embodiment, an ACPA) and the sensor 104 (in the present embodiment, a dipole antenna) is desired. In the present disclosure, optimizations of the antenna element 106 and the sensor 104 were performed using simulations, for example, by the use of a commercially available three-dimensional (3D) electromagnetic (EM) simulator.

In the present embodiment, the antenna element 106 was first optimized without the sensor 104 to achieve a wide bandwidth response, usually with 2 resonances in the S11 parameter of the patch antenna 110. The parameters of the antenna element 106, including a shape of the aperture 110, a design of the patch antenna 110 and/or dielectric thicknesses, were used to improve the bandwidth of the patch antenna 110. The main parameters in relation to the ACPA 106 of the present embodiment used for optimization are shown in relation to FIG. 6. This includes an aperture length 606, an aperture width 608, a length of the end portion 604 (i.e. equal to the aperture width 608 plus 2 times H length 610), a width of the end portion 604 (i.e. H width 612), and a length of the antenna feed line (i.e. feed length 614). A length of the dipole antenna (i.e. dipole antenna length 616) used for optimizing the dipole antenna is also shown.

In the present embodiment, a gap 618 of the dipole antenna is set to a minimum of the PCB manufacturing design rule. After achieving a wide bandwidth response by optimizing the parameters of the antenna element 106, the dipole antenna length 616 is tuned or optimized.

As shown in relation to FIG. 6, a dipole antenna 104 has a sensor longitudinal axis 620 and the antenna feed line 108 is in the form of an elongated shape and has a longitudinal axis. For optimum coupling efficiency, the antenna feed line 108 is arranged to overlap with the dipole antenna 104 and to have the longitudinal axis of the antenna feed line substantially parallel to the sensor longitudinal axis 620 of the dipole antenna 104. In the present embodiment, the longitudinal axis of the antenna feed line is parallel and overlapping with the sensor longitudinal axis 620 of the dipole antenna 104. Further, as shown in relation to FIG. 6, the aperture 114 is arranged to overlap with the dipole antenna 104 and to have the elongated portion 602 of the aperture 114 substantially perpendicular to the sensor longitudinal axis 620. In the present embodiment, the aperture 114 is arranged to overlap with the dipole antenna 104 at approximately the center of the dipole antenna 104.

In the present embodiment, thicknesses of the dielectric layers 116, 118, a height of the solder ball, and the number of metal layers present in the ACPA 106 can be fixed so that formation of the ACPA 106 on the substrate is not changed. These external package parameters may be designed according to the current manufacturing capabilities. The additional process step for forming the antenna module 100 of the present disclosure therefore only relates to the formation of the sensor 104 on the substrate 102 prior to providing the ACPA 106 on the substrate. The external package design of the AiP such as the dielectric and the solder bump height can also be designed based on the current manufacturing capabilities.

FIG. 7 shows a variety of aperture shapes for use in the antenna module 100 of FIG. 1A in accordance with an embodiment. This includes a rectangular shape 702, a H-shape 704, a bowtie-shape 706 and an hour-glass shape 708.

FIG. 8 is a simulated graph 800 of decibel versus frequency to illustrate a response of the patch antenna 110 without the presence of the sensor 104 in accordance with an embodiment. The response of the patch antenna 110 as shown in the simulated graph 800 was recorded after optimizing the design of the antenna element 106. The simulated graph 800 shows that the simulated −10 dB S11 bandwidth is 7.6 GHz, from approximately 26.4 GHz to 34 GHz. The in-situ sensor 104 was then introduced to the antenna module 106 and the response of the patch antenna 110 in the presence of the sensor 104 for varying dipole antenna length 616 was investigated.

FIG. 9 is a simulated graph 900 of decibel versus frequency to illustrate a response of the patch antenna 110 in the presence of the sensor 104 for varying sensor length in accordance with an embodiment. The simulated graph 900 shows the S11 response of the patch antenna 110 for varying dipole antenna length 616, where a response plot 902 is for a dipole antenna length 616 of 1.8 mm, a response plot 904 is for a dipole antenna length 616 of 2 mm, a response plot 906 is for a dipole antenna length 616 of 2.2 mm, a response plot 908 is for a dipole antenna length 616 of 2.4 mm, a response plot 910 is for a dipole antenna length 616 of 2.6 mm and a response plot 912 is for a dipole antenna length 616 of 2.8 mm.

From the simulated graph 900, it is shown that the −10 dB S11 bandwidth is increased when the dipole antenna length 616 is increased. The maximum −10 dB S11 bandwidth in the simulated graph 900 was achieved with the dipole antenna length of 2.8 mm, where the −10 dB S11 bandwidth is 9.4 GHz from ~25.4 GHz to 34.8 GHz. This is about 20% improvement as compared to the bandwidth of the patch antenna 110 without the dipole antenna 104. For the dipole antenna length of 1.8 mm, although the bandwidth is 7.8 GHz, which is similar to the patch antenna 110 without the dipole antenna 104 as shown in the simulated graph 800, it has a better S11 response with a minimum of approximately −12.5 dB within the bandwidth. This provides a higher manufacturing tolerance for forming the antenna element 106.

FIG. 10 is a simulated graph 1000 of decibel versus frequency to illustrate a coupled power of the sensor 104 with the patch antenna 110 for varying sensor length in accordance with an embodiment.

For monitoring and calibrating an output or a performance of the patch antenna 110, RF signal from an input/output (I/O) of the dipole antenna 104 was measured. The simulated coupled power (in decibel), being the ratio of the output of the dipole antenna 104 measured at the second simulation port 126 to the input of the patch antenna 110 measured at the first simulation port 124, is plotted in the graph 1000. A coupled-power plot 1002 is for a dipole antenna length 616 of 1.8 mm, a coupled-power plot 1004 is for a dipole antenna length 616 of 2 mm, a coupled-power plot 1006 is for a dipole antenna length 616 of 2.2 mm, a coupled-power plot 1008 is for a dipole antenna length 616 of 2.4 mm, a coupled-power plot 1010 is for a dipole antenna length 616 of 2.6 mm and a coupled-power plot 1012 is for a dipole antenna length 616 of 2.8 mm.

The simulation results as shown in the graph 1000 shows that the coupled power increases when the dipole antenna length 616 increases. Therefore, depending on the required power for the measurement or calibration of the antenna, a length of the dipole antenna sensor 104 can be set accordingly.

Based on the above simulation results, it is shown that the dipole antenna sensor 104, used as a measurement circuit, can be integrated through codesign with the antenna element 106 and can be coupled to the patch antenna 110 to provide calibration and monitoring measurements for the antenna element 106.

As described in relation to the above Figures, the present disclosure provides an antenna module comprising a sensor formed/provided at a backside of an antenna element/antenna on a substrate/PCB to measure a back-radiation of the antenna element/antenna for monitoring a performance of the antenna element/antenna. The sensor can be integrated with the substrate/PCB for forming the antenna module with the antenna element (e.g. an AiP) being provided/attached on top of the sensor and the substrate/PCB. In an antenna array, the sensor can be provided at the back of each antenna element, and can be used to calibrate the antenna array. The sensor measures the back-radiation field which can provide information in relation to the performance of the MMIC (e.g. the MMIC RF output signal) and the antenna circuit of the antenna element.

To maximize a performance of the sensor, it is desired to codesign the sensor (in this case, a dipole antenna) with the antenna element to achieve the desired coupling power and to avoid affecting the performance of the antenna. With suitable optimization, the presence of the sensor can improve a bandwidth of the antenna element. For example, in the present embodiments where the sensor includes a dipole antenna, increasing the dipole antenna length increases the coupled power and improves the antenna bandwidth. There was no observable adverse effect on the antenna response due to the dipole antenna sensor. It is also noted that if the dipole antenna length is not extended near to an end of the antenna feed line, there is insignificant effect on the antenna performance. On another note, if the dipole antenna length is extended beyond the antenna feed line, it can help to increase the bandwidth of the antenna.

It is also noted that formation of the antenna module, including formation of the sensor and the antenna element, can be performed using conventional fabrication methods/techniques for forming an antenna or an antenna system/array.

Other alternative embodiments of the invention include: (i) optimizing a distance between the antenna and the sensor which has a direct impact on the coupling power and the antenna performance. For example, where the antenna element includes an ACPA and the sensor include a dipole antenna, a height of the solder balls for electrically connecting the ACPA to the substrate/PCB can be optimized; (ii) an antenna element comprising other aperture-coupled antenna designs or antenna where the backside can be accessed can be used; (iii) an antenna element comprising a dual polarized antenna, and in this case, a second sensor can be included for measuring the back-radiation output from the antenna and it can be placed orthogonally with respect to the first sensor on the substrate; (iv) the sensor adapted to receive a calibration signal and to transmit the calibration signal as electromagnetic waves to the antenna element for calibrating the antenna element; (v) other suitable sensor in place of the dipole antenna, e.g. an inductor; (vi) placing the sensor at an angle to the antenna feed line where the sensor is not parallel to the antenna feed line; and (vii) placing the sensor at an angle to the aperture/slit where the angle is not 90°.

Although only certain embodiments of the present invention have been described in detail, many variations are possible in accordance with the appended claims. For example, features described in relation to one embodiment may be incorporated into one or more other embodiments and vice versa.

1. An antenna module comprising:
a substrate;
a first sensor formed on the substrate; and
an antenna element provided on the first sensor, the antenna element being adapted to emit electromagnetic waves in a direction away from the substrate to form a main radiation field and in a direction toward the substrate to form a back-radiation field,
wherein the first sensor is formed between the substrate and the antenna element and is adapted to measure the back-radiation field emitted by the antenna element.

2. The antenna module according to claim 1, wherein the antenna element comprises:
an antenna feed line provided on and spaced apart from the first sensor;
a ground plane having an aperture, the ground plane being formed on the antenna feed line; and
a patch antenna formed over the aperture and the antenna feed line, the patch antenna being adapted to emit the electromagnetic waves,
wherein the antenna feed line is electrically connected to a radio-frequency (RF) output of a monolithic microwave integrated circuit (MMIC) or a radio-frequency integrated circuit (RFIC) and is capacitively coupled to the patch antenna through the aperture for controlling emission of the electromagnetic waves.

3. The antenna module according to claim 2, wherein the first sensor comprises a dipole antenna having a sensor longitudinal axis and the antenna feed line is in the form of an elongated shape and having a longitudinal axis, the antenna feed line is arranged to overlap with the dipole antenna and to have the longitudinal axis of the antenna feed line substantially parallel to the sensor longitudinal axis.

4. The antenna module according to claim 3, wherein the aperture is in the form of a H-shape having an elongated portion and two end portions formed at each end of the elongated portion, and each of the two end portions are perpendicular to the elongated portion.

5. The antenna module according to claim 4, wherein the aperture is arranged to overlap with the dipole antenna and to have the elongated portion of the aperture substantially perpendicular to the sensor longitudinal axis.

6. The antenna module according to claim 2, wherein the antenna feed line, the ground plane and the patch antenna are integrated to form an antenna-in-package (AIP) structure.

7. The antenna module according to claim 1, wherein the first sensor comprises an inductor.

8. The antenna module according to claim 1, further comprising:
a second sensor provided on the substrate, wherein the second sensor is arranged substantially orthogonally to the first sensor and is adapted to measure the back-radiation field from the antenna element.

9. The antenna module according to claim 1, wherein the first sensor is further adapted to receive a calibration signal and to transmit the calibration signal as calibration electromagnetic waves to the antenna element for calibrating the antenna element.

10. A method of forming an antenna module, the method comprising:
providing a substrate;
forming a first sensor on the substrate; and
providing an antenna element on the first sensor, the antenna element being adapted to emit electromagnetic waves in a direction away from the substrate to form a main radiation field and in a direction toward the substrate to form a back-radiation field,
wherein the first sensor is formed between the substrate and the antenna element and is adapted to measure the back-radiation field emitted by the antenna element.

11. The method according to claim 10, wherein providing the antenna element on the first sensor comprises:
providing an antenna feed line on and spaced apart from the first sensor;
forming a ground plane having an aperture on the antenna feed line; and
forming a patch antenna over the aperture and the antenna feed line, the patch antenna being adapted to emit the electromagnetic waves,
wherein the antenna feed line is electrically connected to a radio-frequency (RF) output of a monolithic microwave integrated circuit (MMIC) or a radio-frequency integrated circuit (RFIC) and is capacitively coupled to the patch antenna through the aperture for controlling emission of the electromagnetic waves.

12. The method according to claim 11, wherein the first sensor comprises a dipole antenna having a sensor longitudinal axis and the antenna feed line is in the form of an elongated shape and having a longitudinal axis, the method further comprises providing the antenna feed line to overlap with the dipole antenna and to have the longitudinal axis of the antenna feed line substantially parallel to the sensor longitudinal axis of the dipole antenna.

13. The method according to claim 12, wherein the aperture is in the form of a H-shape having an elongated portion and two end portions formed at each end of the elongated portion, and each of the two end portions are perpendicular to the elongated portion.

14. The method according to claim 13, wherein forming the ground plane having the aperture on the antenna feed line comprises arranging the aperture to overlap with the dipole antenna and to have the elongated portion of the aperture substantially perpendicular to the sensor longitudinal axis.

15. The method according to claim 11, wherein the antenna feed line, the ground plane and the patch antenna are integrated to form an antenna-in-package (AIP) structure.

16. The method according to claim 10, wherein the first sensor comprises an inductor.

17. The method according to claim 10, further comprising providing a second sensor on the substrate, wherein the second sensor is arranged substantially orthogonally to the first sensor and is adapted to measure the back-radiation field from the antenna element.

18. The method according to claim 12, further comprising:
optimizing parameters associated with the antenna element to maximize a bandwidth of the patch antenna, the parameters include a shape of the aperture, dimensions of the patch antenna and a separation distance between the patch antenna and the ground plane; and
optimizing a length of the dipole antenna based on the optimized parameters associated with the antenna element to maximize a coupled power between the dipole antenna and the antenna element.

19. The method according to claim 10, wherein the substrate includes a printed-circuit board (PCB) having a ground layer on a top surface of the PCB, forming the first sensor on the substrate comprises removing a portion of the ground layer on the top surface of the PCB and forming the first sensor on a portion of the top surface of the PCB at which the portion of the ground layer is removed.
